(19) United States
(12) Patent Application Publication
(10) Pub. No.: US 2025/0364497 A1
(43) Pub. Date: Nov. 27, 2025

(54) DUMMY DIES AND METHOD OF FORMING THE SAME

(71) Applicant: TAIWAN SEMICONDUCTOR MANUFACTURING COMPANY, LTD., Hsinchu (TW)

(72) Inventors: Hsing-Yuan HUANG, Hsinchu (TW); Yi Chen HO, Taichung (TW)

(21) Appl. No.: 19/294,331

(22) Filed: Aug. 8, 2025

Related U.S. Application Data
(63) Continuation of application No. 18/498,031, filed on Oct. 30, 2023.
(60) Provisional application No. 63/525,236, filed on Jul. 6, 2023.

(51) Int. Cl. H01L 25/065; H01L 23/00; H01L 23/36; H01L 25/00

(52) U.S. Cl. CPC H01L 25/0657; H01L 23/36; H01L 23/562; H01L 24/29; H01L 24/32; H01L 24/94; H01L 25/50; H01L 2224/29005; H01L 2224/29187; H01L 2224/32145; H01L 2224/94; H01L 2924/181; H01L 2924/3511

(57) ABSTRACT

The present disclosure provides a dummy die with improved thermal conductivity and warpage control. The dummy die includes an adjustment layer formed over a semiconductor substrate. The adjustment layer has a thermal conductivity in a range between about 30 W/mK and about 100 W/mK. The adjustment layer may include silicon nitride or silicon carbide.

### CROSS-REFERENCE TO RELATED APPLICATIONS

This application is a continuation of U.S. patent application Ser. No. 18/498,031 filed Oct. 30, 2023, which claims priority to the U.S. Provisional Patent Application Ser. No. 63/525,236 filed Jul. 6, 2023. Each of the aforementioned applications is incorporated by reference in its entirety.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer, and individual dies on the wafer are singulated by sawing between the integrated circuits along a scribe line. The individual dies are typically packaged separately, in multi-chip modules, or in other types of packaging, for example.

Three-dimensional integrated circuits (3DICs) are a relatively recent development in semiconductor packaging in which multiple semiconductor dies are stacked upon one another, such as package-on-package (POP) and system-in-package (SiP) packaging techniques. A 3DIC may provide improved integration density and other advantages, such as faster speeds and higher bandwidth, because of the decreased length of interconnects between the stacked dies, as examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram of forming of dummy dies according to embodiments of the present disclosure.

FIGS. 2-8, 9A-9E, and 10 schematically demonstrate various processing stages during fabrication of dummy dies according to embodiments of the present disclosure.

FIG. 11 shows improved thermal conductivity in dummy dies according to embodiments of the present disclosure.

FIGS. 12A and 12B schematically demonstrate improved warpage control in dummy dies according to embodiments of the present disclosure.

FIG. 13 is a flow diagram of forming of an integrated circuit package according to embodiments of the present disclosure.

FIGS. 14, 15, 16A-16C, 17A-17B, and 18-21 schematically demonstrate various processing stages during fabrication of an integrated circuit package according to embodiments of the present disclosure.

FIG. 22 is a flow diagram of forming of an integrated circuit package according to embodiments of the present disclosure.

FIGS. 23A-23D, 24A-24C, and 25 schematically demonstrate various processing stages during fabrication of an integrated circuit package according to embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will be described with respect to embodiments in a specific context, namely an integrated circuit package. Other embodiments may also be applied, however, to other electrically connected components, including, but not limited to, package-on-package assemblies, die-to-die assemblies, wafer-to-wafer assemblies, die-to-substrate assemblies, die-to-wafer assemblies, in assembling packaging, in processing substrates, interposers, or the like, or mounting input components, boards, dies or other components, or for connection packaging or mounting combinations of any type of integrated circuit or electrical component. Various embodiments described herein allow for packaging functional components (such as, for example, integrated circuit dies) of varying functionalities and dimensions (such as, for example, heights) in a same integrated circuit package. Various embodiments described herein may be integrated into a chip-on-wafer-on-substrate (CoWoS) process and a chip-on-chip-on-substrate (CoCoS) process.

Embodiments of the present disclosure relates to a dummy die with an adjustment layer to increase thermal conductivity and warpage control. The adjustment layer may include one or more layer of materials having thermal conductivity in a range between about 30 W/mK and about 100 W/mK. In some embodiments, the adjustment layer may include silicon nitride or silicon carbide. In some embodiments, dummy dies may be bond with another die by a bonding film including dummy conductors formed therein to further improve thermal conductivity.

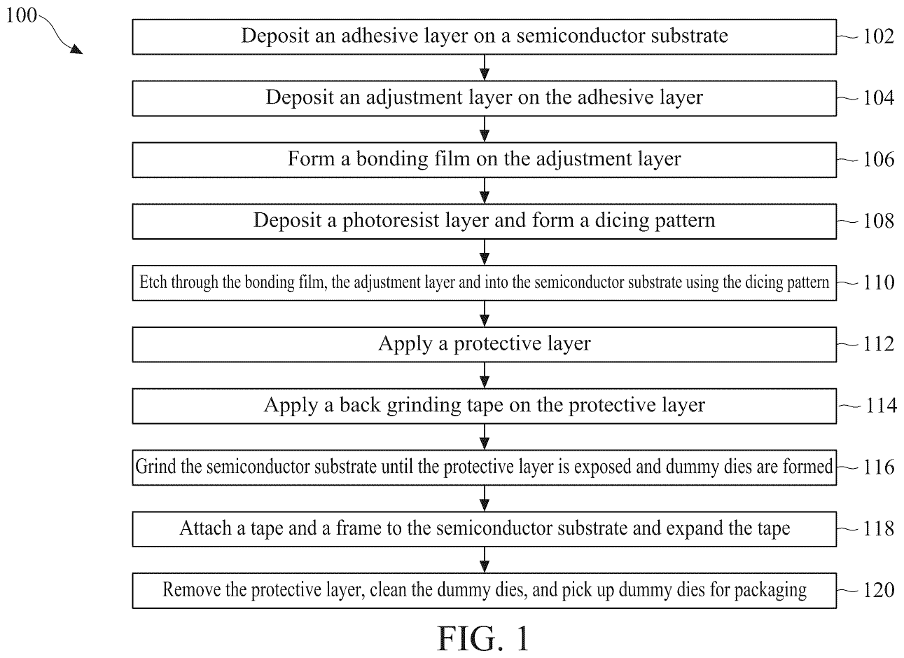

FIG. 1 is a flow diagram of a method 100 of forming of dummy dies according to embodiments of the present disclosure. Particularly, the method 100 forms dummy dies used in SoIC (system on integrated circuit) packaging with improved thermal conductivity. A dummy die may be regarded as a device-free die. A dummy die is substantially free of any electronic devices. For example, a dummy die is substantially free of any active components or functional components, such as transistors, capacitors, resistors, diodes, photodiodes, fuse devices and/or other similar devices. A dummy die may include a semiconductor substrate and a bonding structure. Embodiments of the present disclosure provide a dummy die with a bonding structure having improved thermal conductivity and/or improved warpage adjustment.

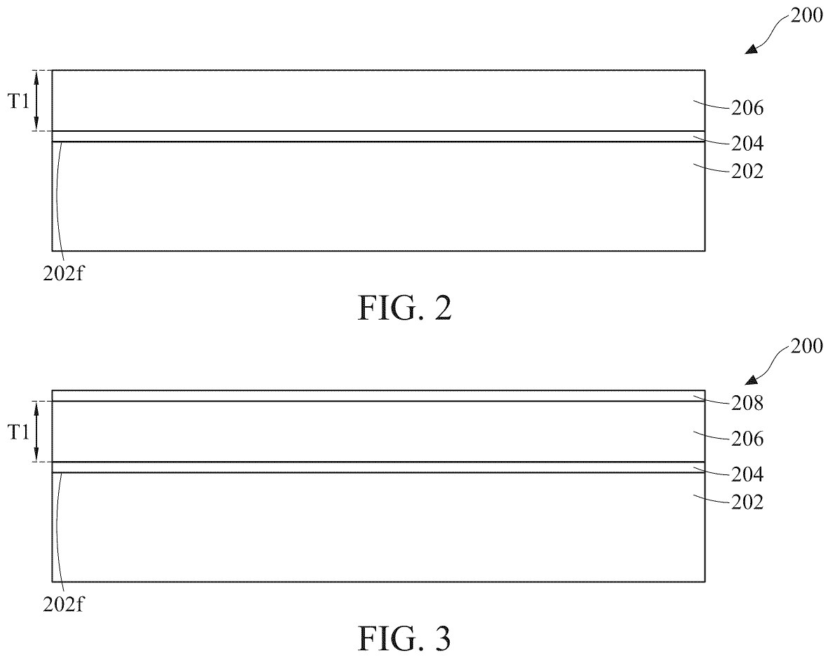

FIGS. 2-8, 9A-9E, and 10 schematically demonstrate various processing stages during fabrication of dummy substrate 200 according to embodiments of the present disclosure. Particularly, FIGS. 2-8, 9A-9E, and 10 demonstrate forming dummy devices using the method 100.

In operation 102, an adhesive layer 204 is deposited on a semiconductor substrate 202, as shown in FIG. 2. FIG. 2 is a schematic partial cross-sectional view of the semiconductor substrate 202. A plurality of dummy substrate 200 are to be formed from the semiconductor substrate 202.

The semiconductor substrate 202 is formed from one or more semiconductor materials. In some embodiments, the semiconductor substrate 202 is a bear substrate including an elementary semiconductor, such as silicon or germanium in a crystalline, a polycrystalline, or an amorphous structure; a compound semiconductor such as silicon carbide, gallium arsenide, gallium phosphide, indium phosphide, indium arsenide, and/or indium antimonide; an alloy semiconductor, such as e.g., silicon-germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), etc.; combinations thereof, or other suitable material. In some embodiments, the semiconductor substrate 202 may include one or more dopants. The semiconductor substrate 202 may also be in the form of silicon-on-insulator (SOI). The SOI substrate may comprise a layer of a semiconductor material, e.g., silicon, germanium and/or the like, formed over an insulator layer, e.g., buried oxide and/or the like, which is formed on a silicon substrate. In addition, other substrates that may be used include multi-layered substrates, gradient substrates, hybrid orientation substrates, any combinations thereof and/or the like.

The adhesive layer 204 is deposited on a front side 202f of the semiconductor substrate 202. In some embodiments, the adhesive layer 204 may be formed by flowing an oxidizing precursor to the processing chamber. In some embodiments, one or more cleaning processes may be performed to remove native oxides and/or contaminations from the semiconductor substrate 202 prior to forming the adhesive layer 204.

The adhesive layer 204 provides adhesion between subsequent layers to be formed on the semiconductor substrate 202. In some embodiments, when the semiconductor substrate 202 comprises silicon, the adhesive layer 204 comprises silicon oxide. In some embodiments, the adhesive layer 204 is formed of USG (undoped silica glass). In some embodiments, the adhesive layer 204 have a thickness in a range between about 100 Å and about 1000 Å. If the thickness of the adhesive layer 204 is less than 100 Å, adhesion effect of the adhesive layer 204 may not provide sufficient adhesion for the subsequent layer to the semiconductor substrate 202 to sustain the subsequent process, such as grinding and planarization, for example, cracks may be formed in the adhesive layer 204. If the thickness of the adhesive layer 204 is greater than 1000 Å, ductility of the adhesive layer 204 may reduce, and a buckling may be formed in the adhesive layer 204.

In operation 104, an adjustment layer 206 is deposited on the semiconductor substrate 202 over the adhesive layer 204, as shown in FIG. 2. In some embodiments, the adjustment layer 206 provides improved heat conductivity in the subsequently formed dummy substrate 200. Additionally, the adjustment layer 206 also provides stress modulation or warpage adjustment to the semiconductor substrate 202.

The adjustment layer 206 has a thickness T1. In some embodiments, the thickness T1 is in a range between about 3000 Å and about 6000 Å. A thickness less than 3000 Å may not provide sufficient thermal conductivity or stress modulation/warpage adjustment. A thickness great than 6000 Å may create too much stress and causing the adjustment layer 206 to peel off from the semiconductor substrate 202.

In some embodiments, the adjustment layer 206 may be a thermal conducting layer having a thermal conductivity in range between about 30 W/mK and about 100 W/mK. In some embodiments, the adjustment layer 206 may include a suitable dielectric film, such as a semiconductor nitride or a semiconductor carbide. In some embodiments, the adjustment layer 206 may include silicon nitride (Si₃N₄ or SiN), Si-rich silicon nitride, a N-rich silicon nitride, silicon carbide, or the like.

In some embodiments, the adjustment layer 206 may be silicon nitride. The adjustment layer 206 may be formed by flowing precursors containing a nitrogen source and a semiconductor source. In some embodiments, the adjustment layer 206 is formed at a low temperature range to improve thermal conductivity and avoid forming hot spots in a SoIC.

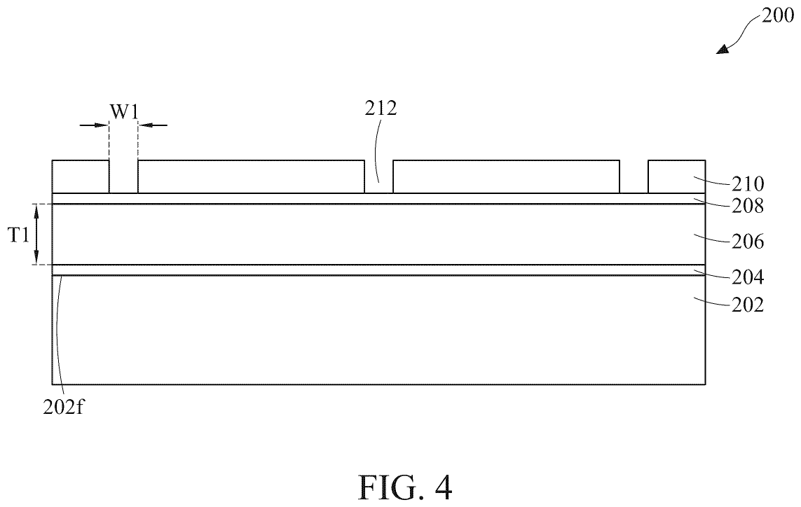

In operation 106, a bonding film 208 is deposited over the adjustment layer 206, as shown in FIG. 3. FIG. 3 is a partial cross-sectional view of the dummy substrate 200 after operation 106. The bonding film 208 is configured to bond the dummy die to be formed with other dies during subsequent packaging. Particularly, the bonding film 208 may be selected from any material suitable to bond the adjustment layer 206 with another die or with another bonding filming. The bonding film 208 may be formed with any suitable material for bonding in packaging. In some embodiments, the bonding film 208 is formed of an oxide material. For example, the bonding film 208 is formed of USG. In some embodiments, the bonding film 208 has a thickness in a range between about 100 Å and about 1000 Å. The thickness of the bonding film 208 may be selected according to the queue time. Because the bonding film 208 may absorb moisture during wait time, it is desirable to have a thinner bonding film 208 to avoid trapping excess moisture in IC packages if there is long queue time for the dummy substrate 200 during packaging.

In operation 108, a photoresist layer 210 is deposited over the bonding film 208 and a dicing pattern is formed in the photoresist layer 210, as shown in FIG. 4. FIG. 4 is a partial cross-sectional view of the dummy substrate 200 after operation 108. The photoresist layer 210 may be deposited over the bonding film 208. A photolithography process is followed to form a dicing pattern with trenches 212 in the photoresist layer 210. The photoresist layer 210 is selectively removed to form the trenches 212. The trenches 212 may form a grid defining a plurality of rectangular areas. As shown in FIG. 4, the bonding film 208 is exposed at the bottom of the trenches 212.

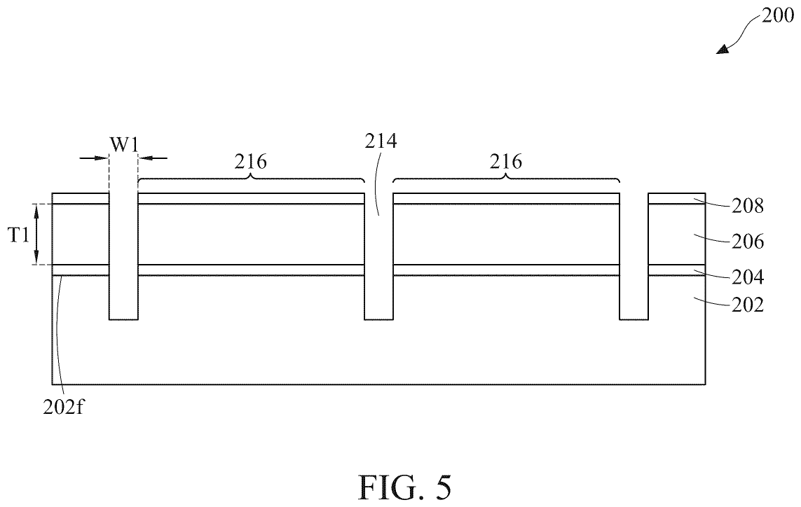

In operation 110, one or more etch processes are performed to etch through the bonding film 208, the adjustment layer 206, the adhesive layer 204, and into the semiconductor substrate 202 forming dicing trenches 214, as shown in FIG. 5. FIG. 5 is a partial cross-sectional view of the dummy substrate 200 after operation 110. The patterned photoresist layer 210 is used as a mask to form the dicing trenches 214. The dicing trenches 214 may form a grid in the bonding film 208, the adjustment layer 206, the adhesive layer 204, and into the semiconductor substrate 202 forming a plurality of dummy areas 216. The dicing trenches 214 are formed into the semiconductor substrate 202 but not through the semiconductor substrate 202 so that the dummy areas 216 remain connected by the semiconductor substrate 202. The dicing trenches 214 are deep enough so that the dummy areas 216 may be separated from one another when the semiconductor substrate 202 is grinded down from the back side. In some embodiments, the dicing trenches 214 have a width W1 in a range between about 6 microns and about 10 microns.

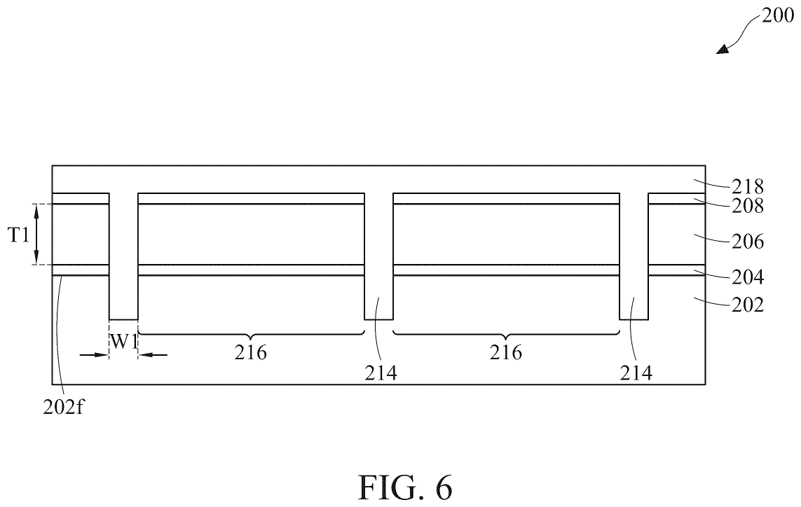

In operation 112, a protective layer 218 is deposited to fill the dicing trenches 214 and cover the dummy areas 216, as shown in FIG. 6. FIG. 6 is a partial cross-sectional view of the dummy substrate 200 after operation 112. The protective layer 218 is used to cover and protect the bonding film 208 and exposed portions of the semiconductor substrate 202, the adhesive layer 204 and the adjustment layer 206 during subsequent processing. The protective layer 218 may be formed by any material that is capable of isolate the dummy areas 216 from the processing environment during the subsequent processing. The protective layer 218 may also be easily removed from the dummy areas 216. In some embodiments, the protective layer 218 may be formed from a photoresist material. In some embodiments, the protective layer 218 may be deposited over the dummy areas 216 by a spin-on coating process followed by a curing process, e.g., a low temperature curing technique. However, any suitable coatings, any suitable deposition techniques, and any suitable curing techniques may also be used. Alternatively, the protective layer 218 may be a curable resin, polyimide coating, polybenzoxazole (PBO), epoxy films, or the like.

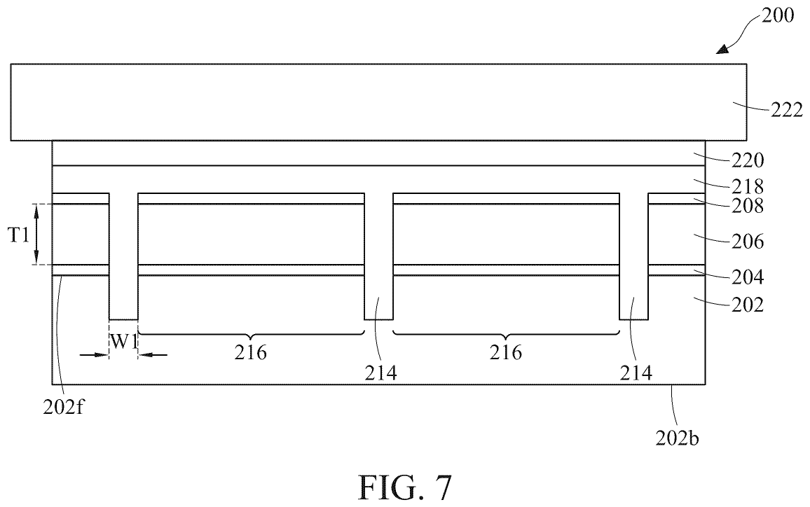

In operation 114, a back grinding tape 220 and a carrier wafer 222 are attached to the protective layer 218, as shown in FIG. 7. FIG. 7 is a partial cross-sectional view of the dummy substrate 200 after operation 114. The back grinding tape 220 is first attached to the protective layer 218. The carrier wafer 222 is then attached to the back grinding tape 220 so that the semiconductor substrate 202 may be thinned down from a back side 202b.

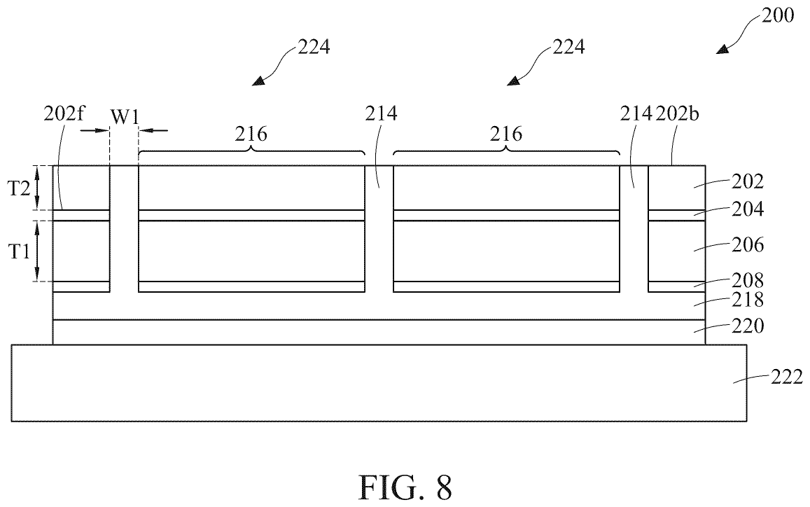

In operation 116, the semiconductor substrate 202 is flipped over and a back grinding process is performed to thin down the semiconductor substrate 202 from the back side 202b, as shown in FIG. 8. FIG. 8 is a partial cross-sectional view of the dummy substrate 200 after operation 118. The back grinding process reduces thickness of the semiconductor substrate 202 to a target thickness according to the design.

In some embodiments, the back grinding process is performed to reduce the thickness of the semiconductor substrate 202 and to “dice” the dummy substrate 200 into a plurality of dummy dies 224. As shown in FIG. 8, the back grinding process removes the portion of the semiconductor substrate 202 without the dicing trenches 214 and exposes the protective layer 218. In some embodiments, the concentration of the protective layer 218 in the grinding waste may be used as an end point for the back grinding process. After the back grinding process, the thickness of the semiconductor substrate 202 is reduced to a thickness T2. In some embodiment, the thickness T2 is in a range between about 50 microns and about 100 microns.

Even though, the dummy dies 224 are fabricated after the operation 114, the plurality of dummy dies 224 remain connected by the protective layer 218. The dummy dies 224 are separated by the dicing trenches 214 which are filled with the protective layer 218. The bonding film 208 on each dummy die 224 is in contact with the protective layer 218, which is attached to the back grinding tape 220.

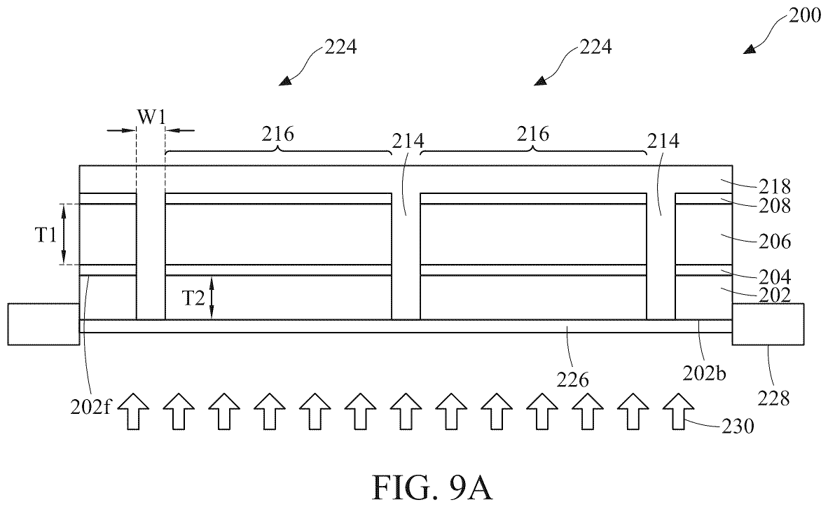

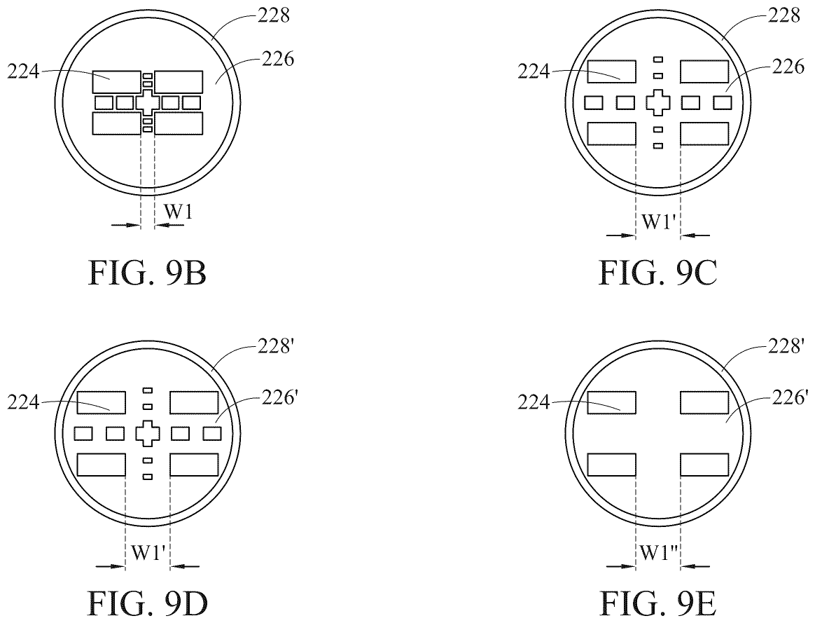

In operation 118, one or more expanding processes are performed to increase the distance between the dummy dies 224, as shown in FIGS. 9A-9E. FIG. 9A is a partial cross-sectional view of the dummy dies 224 after operation 118. FIGS. 9B and 9C are schematic top views of the plurality of dummy dies 224 before and after an expansion process. FIGS. 9D and 9E are schematic top views of the plurality of dummy dies 224 before and after a second expansion process.

After the back grinding process, the plurality of dummy dies 224 are flipped over and attached to an expansion tape 226 on a frame 228. As shown in FIG. 9A, the plurality of dummy dies 224 are glued to the expansion tape 226 at the back side 202b. The carrier wafer 222 and the back grinding tape 220 are then removed. The expansion tape 226 is then stretched so that the dicing trenches 214 between the dummy dies 224 widens.

In some embodiments, ultra-violet radiation 230 may be applied to the expansion tape 226 so that the expansion tape 226 may be relaxed and stretched to increase the distance between neighboring dummy dies 224. As shown in FIG. 9B, prior to the expansion process, the distance between neighboring dummy dies 224 is the width W1 of the dicing trenches 214. As discussed above, the width W1 is in a range between about 6 microns and about 10 microns. As shown in FIG. 9C, after the expansion tape 226 is stretched, the distance between neighboring dummy dies 224 is a width W1′. In some embodiments, the width W1′ may be in a range between about 60 microns and about 65 microns. The expanded distance W1′ allows the dummy dies 224 to be individually picked up from the expansion tape 226 for subsequent packaging.

In some embodiments, one or more additional expansion processes may be performed to further increase the distance between neighboring dummy dies 224 for ease of handling. As shown in FIG. 9D, the dummy dies 224 may be transferred from the expansion tape 226 on the frame 228 to a second expansion tape 226′ on a second frame 228′. In FIG. 9E, the second expansion tape 226′ is stretched and the distance between neighboring dummy dies 224 increases to a distance W1″. In some embodiments, the width W1″ may be in a range between about 450 microns and about 550 microns. Even though two expansion processes are shown in the example, more or less expansions may be used to realize desirable distance between the dummy dies 224 so that the dummy dies 224 may be picked up by die handling tools.

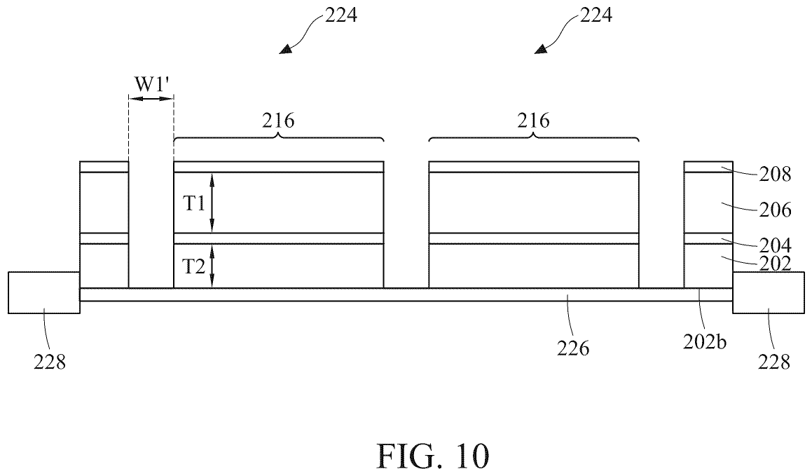

In operation 120, the dummy dies 224 are cleaned and ready for subsequent packaging, as shown in FIG. 10. FIG. 10 is a partial cross-sectional view of the dummy dies 224 after operation 120. The dummy dies 224 are cleaned to remove the protective layer 218 by a suitable process, for example, by an ashing process when the protective layer 218 includes photoresist material. After cleaning, the bonding film 208 on each dummy die 224 is exposed. The extended distance W1″ allows the dummy dies 224 to be picked up individually from the expansion tape 226′ for packaging.

The dummy die 224 according to the present disclosure includes an adjustment layer, such as the adjustment layer 206, deposited on a semiconductor substrate 202 in place of oxide based bonding films. The adjustment layer 206 is formed by a material with higher thermal conductivity therefore improving heat dissipation in IC packages. The adjustment layer 206 may also be a high stress layer to improve wafer warpage control, thus, improving bonding quality.

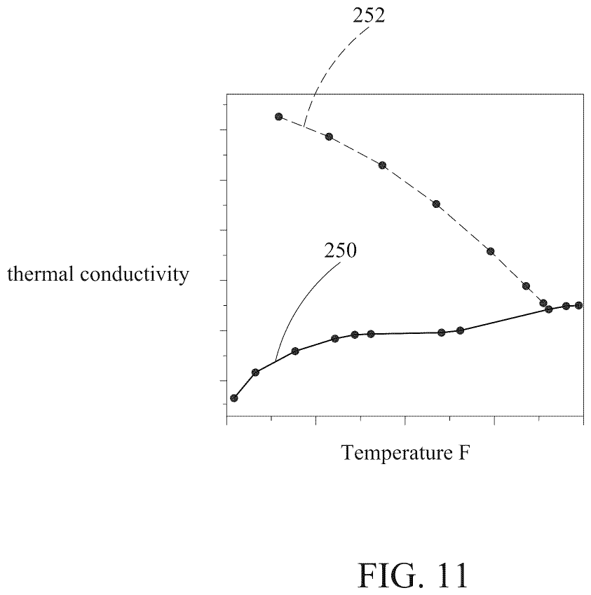

FIG. 11 includes thermal conductivity and temperature curves of silicon oxide and silicon nitride. Curve 250 is thermal conductivity and temperature curve of silicon oxide. Curve 252 is thermal conductivity and temperature curve of silicon nitride. Silicon oxide is used in dummy dies according to the current state of the art. Silicon oxide facilitates bonding between a dummy die to other dies in an IC package. According to embodiments of the present disclosure, the adjustment layer 206 is used to replace silicon oxide in dummy dies. The adjustment layer 206 may be formed by silicon nitride. As shown in FIG. 11, the thermal conductivity of silicon nitride is much higher than the thermal conductivity of the silicon oxide, particularly at low temperatures. For example, at 25° C., the thermal conductivity of silicon nitride is about 55 W/mK while the thermal conductivity of silicon oxide is about 25 W/mK. Thus, by using the adjustment layer 206 with silicon nitride to replace silicon oxide layer, embodiments of the present disclosure improve heat dissipation in the bonding region between dummy dies and device dies.

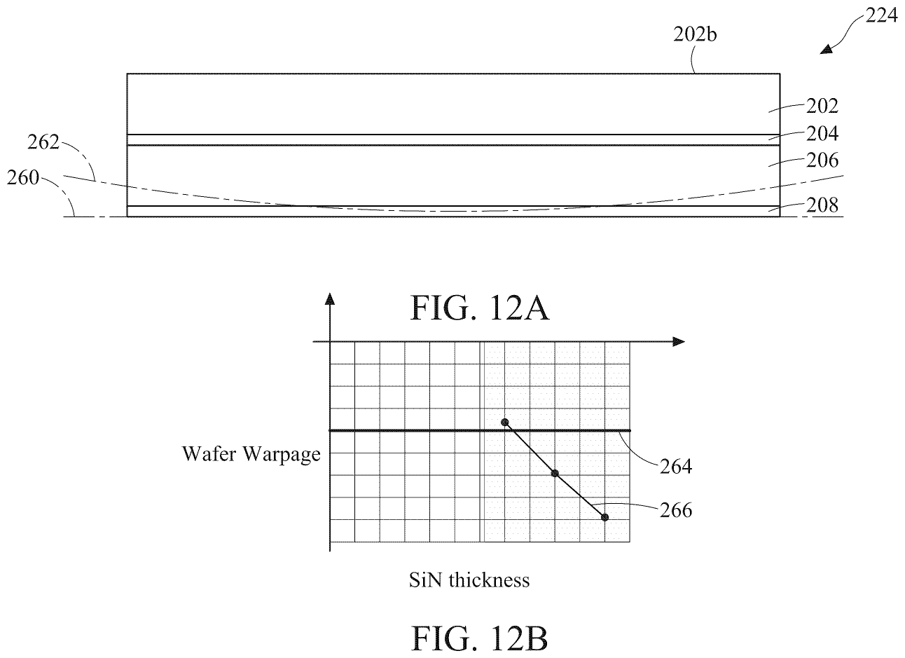

In some embodiments, the adjustment layer 206 is designed to achieve desirable warpage. For example, a negative warpage may be desired in a dummy die to improve bonding quality. A negative warpage is defined when a substrate is warped towards its back side. FIG. 12A is schematic sectional view of a dummy die 224 to illustrate negative warpage. In FIG. 12A, the dummy die 224 is positioned with the back side 202b of the semiconductor substrate 202 facing up and the bonding film 208 facing down. When the dummy die 224 has no warpage, a profile 260 of the dummy die 224 is planar. When the dummy die 224 has a negative warpage, the profile of the dummy die 224 is represented by the curve 262. With a negative warpage, the bonding film 208 first would contact the die to be bonded at the center region, and the contact area would expand from the center region to the edge region, thus, improving high bonding quality.

In state-of-the art technology, a negative warpage is achieved by depositing a certain thickness of silicon oxide. For example, a silicon oxide layer having a thickness in a range between about 15 k angstroms and 20 k angstroms is applied to a semiconductor substrate to achieve a negative warpage to improve bonding quality. The adjustment layer 206 according to the present disclosure may achieve the same or more negative warpage at lesser thickness.

FIG. 12B schematically demonstrates of warpages corresponding to thickness of the adjustment layer 206. Line 264 marks the negative warpage in a wafer with a silicon oxide film having a thickness between 15 k angstroms and 20 k angstrom. Line 266 indicates shows the warpage values from the adjustment layer 206 according to the present disclosure. The adjustment layer 206 is formed from silicon nitride. When the adjustment layer 206 has a thickness of 3.5 k angstroms, the negative warpage in the dummy die 224 is slightly less than the negative warpage achieved by a silicon oxide film having a thickness between 15 k angstroms and 20 k angstrom. When the adjustment layer 206 has a thickness of 4.5 k angstroms, the negative warpage in the dummy die 224 is about 50% greater than the negative warpage achieved by a silicon oxide film having a thickness between 15 k angstroms and 20 k angstrom. When the adjustment layer 206 has a thickness of 5.5 k angstroms, the negative warpage in the dummy die 224 is about twice the negative warpage achieved by a silicon oxide film having a thickness between 15 k angstroms and 20 k angstrom.

As shown in FIG. 12B, the adjustment layer 206 according to the present disclosure may achieve an equal amount or more negative warpage in with a much thinner film. The reduced thickness between the dummy die and the die to be bonded further improves heat dissipation.

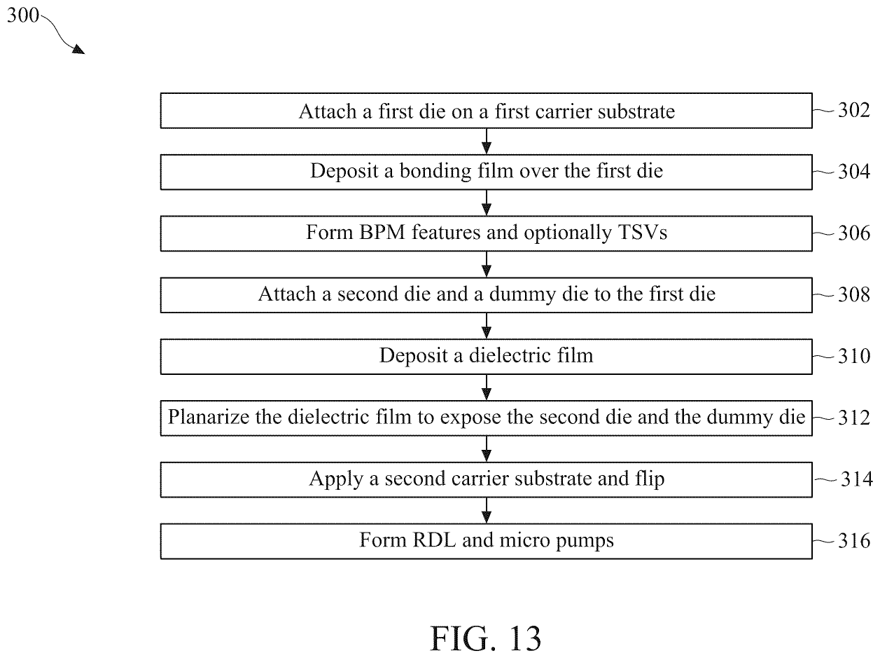

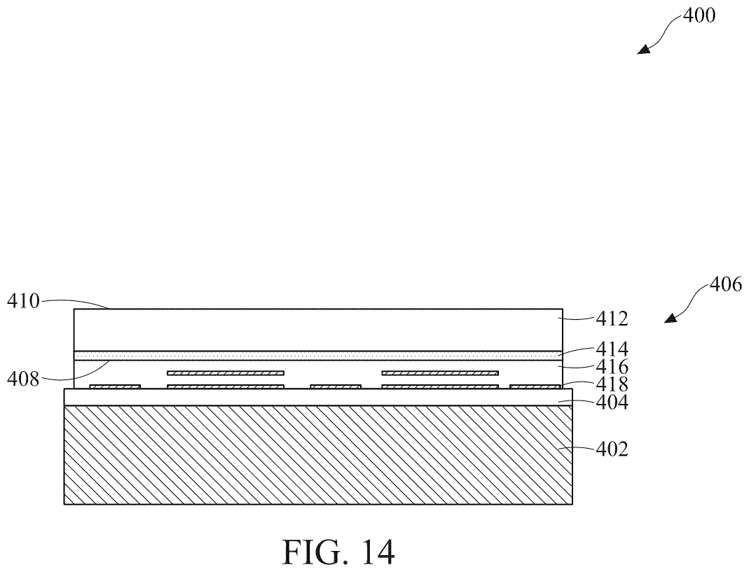

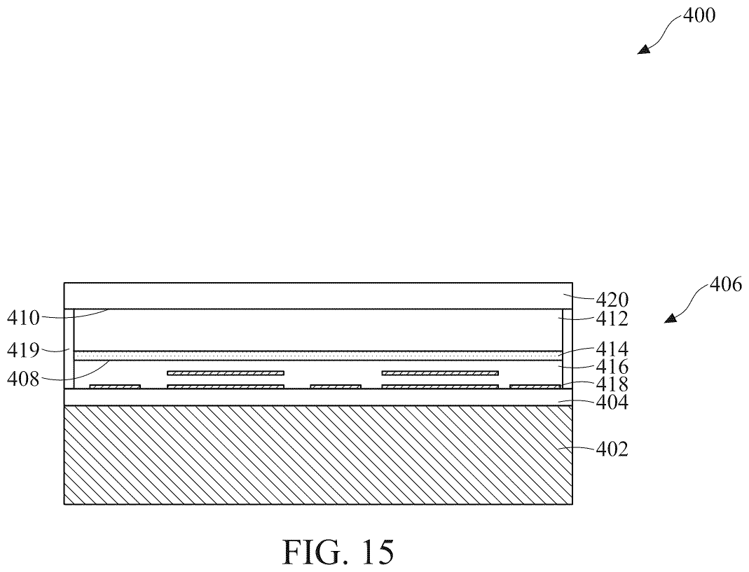

FIG. 13 is a flow diagram illustrating a method 300 of forming of an integrated circuit package according to embodiments of the present disclosure. Dummy dies according to the present disclosure may be used in the method 300. FIGS. 14-24 schematic demonstrates various processing stages during fabrication of an integrated circuit (IC) package 400 according to embodiments of the present disclosure. The IC package 400 may be fabricated using the method 300.

The method 300 may be used to form a 3DIC (three-dimensional integrated circuit) package. In a typical formation process of forming a 3DIC, two layers of dies are vertically stacked, and electrical connections are formed between the two layers of dies. For example, a top die is stacked over a bottom die. The top die and the bottom die may have different dimensions. Dummy dies may be used to make up the dimension difference between the top die and the bottom dies. In the method 300, a larger bottom die is bonded to a smaller top die and one or more dummy dies. It should be noted that the terms “top die” and “bottom die” are used for clarity in description, and not necessarily referred to the physical position of the dies.

In operation 302, a first die 406 is attached to a carrier wafer 402 for bonding a second die, as shown in FIG. 14. FIG. 14 is a schematic cross-sectional view of the IC package 400 after operation 302. The first die 406 may be referred to as a bottom die is attached to the carrier wafer 402 via an adhesive layer 404.

The first die 406 may be a logic die, a memory die, a 3DIC die, a CPU (computation process unit) die, a GPU (graphic process unit) die, a SoC (system-on-chip) die, a MEMS die, or the like. The first die 406 may be a single die or a composition die, such as a chiplet having two or more dies. In some embodiments, the first die 406 may be a chiplet that includes two or more cores, CPU processors, GPU (processors, and a bus network connecting the two or more cores. From a top view, the first die 406 may be in a quadrilateral, a rectangular or a square shape.

The carrier wafer 402 may comprise, for example, glass, silicon oxide, aluminum oxide, and the like. The adhesive layer 404 is applied to the carrier wafer 402. Alternatively, the carrier wafer 402 may comprise a carrier tape. The adhesive layer 404 may be used to glue the carrier wafer 402 to other devices such as the first die 406. In some embodiments, the adhesive layer 404 may be a thermal release film. In some embodiments, the adhesive layer 404 may be an ultraviolet (UV) glue, which loses its adhesive property when exposed to UV lights. Any suitable adhesive may be utilized, and all such adhesives are fully intended to be included within the scope of the present disclosure.

The first die 406 may include a substrate 412, a device layer 414 formed in and on the substrate 412, and an interconnect structure 416 formed on the device layer 414. The interconnect structure 416 may include multiplayers of dielectric materials having conductive features 418 formed therein.

The substrate 412 may comprise bulk silicon, doped or undoped, or an active layer of a SOI substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates. The substrate 412 has a front side 408 and a back side 410. The device layer 414 is formed on the front side 408 of the substrate 412. In operation 302, the first die 406 is attached to the carrier wafer 402 such that the back side 410 of substrate 412 faces up for subsequent bonding.

The device layer 414 include a variety of devices, such as transistors, capacitors, resistors, inductors and the like, which may be used to generate the desired structural and functional requirements of the design for the first die 406.

The interconnect structure 416 is formed over the front side 408 of the substrate 412 over the device layer 414. The conductive features 418 embedded in the interconnect structure 416 are designed to connect the various devices in the device layer 414 to form functional circuitry. The interconnect structure 416 is formed of alternating layers of dielectric and conductive material and may be formed through any suitable processes, such as deposition, damascene, dual damascene, etc.

In operation 304, a bonding film 420 is deposited over the first die 406, as shown in FIG. 15. FIG. 15 is a schematic cross-sectional view of the IC package 400 after operation 304. In some embodiments, a grinding process may be performed to thin down the substrate 412 to a desired thickness prior to depositing the bonding film 420.

Even though only a single first die 406 is shown in FIG. 14 in the first layer, during packaging process, a plurality of dies may be placed over the carrier wafer 402 to be processed simultaneously. A filling material 419 may be injected within cavities between the neighboring dies. In some embodiments, the filling material 419 may include epoxy, resin, molding compounds resin, or the like. After the filling material 419 is placed into cavities between the dies, the filling material 419 may be cured to harden the filling material 419 for optimum protection. While the exact curing process is dependent at least in part on the particular material chosen for the filling material 419. In some embodiments, the filling material 419 may be cured by heating the filling material 419 to a temperature between about 100° C. and about 130° C. A chemical mechanical polishing (CMP) process may be performed to remove the filling material 419 deposited over the first die 406 and to thin down the substrate 412 in the first die 406.

In some embodiments, the bonding film 420 may be formed of silicon oxide, silicon oxynitride, silicon nitride, or low-k dielectric materials having k values lower than about 3.0. The low-k dielectric materials may include a carbon-containing low-k dielectric material, Hydrogen SilsesQuioxane (HSQ), MethylSilsesQuioxane (MSQ), or the like. In some embodiments, the bonding film 420 may be formed by suitable fabrication techniques such as chemical vapor deposition (CVD), High-Density Plasma Chemical Vapor Deposition (HDPCVD) or plasma-enhanced chemical vapor deposition (PECVD).

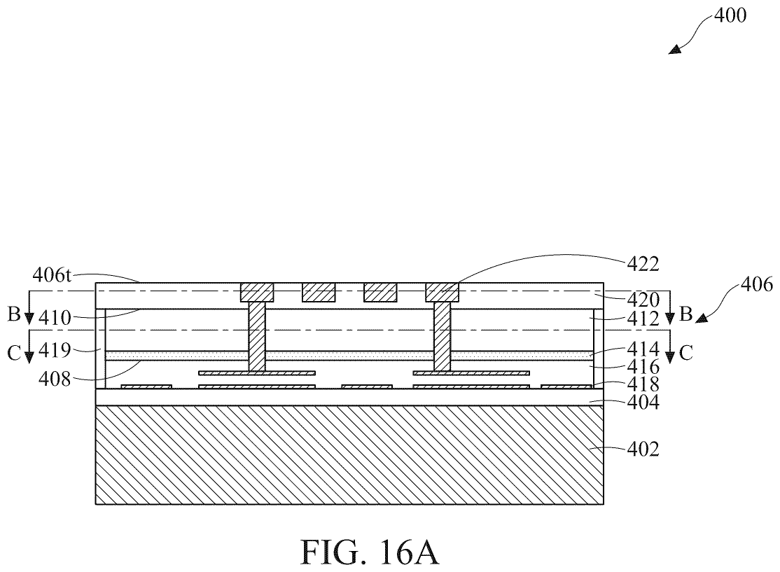

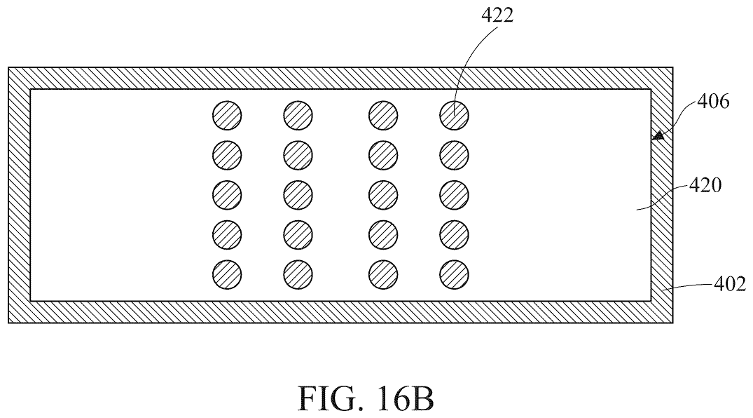

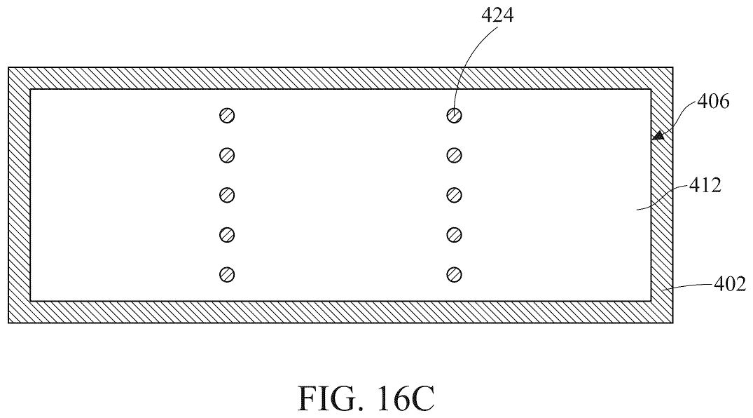

In operation 306, bond pad features 422, also referred to as bond pad metals (BPMs) are formed in the bonding film 420, as shown in FIGS. 16A, 16B, and 16C. FIG. 16A is a schematic cross-sectional view of the IC package 400 after operation 306. FIG. 16B is a plane view of the IC package along B-B line on FIG. 16A. FIG. 16C is a plane view of the IC package along C-C line on FIG. 16A.

The bond pad features 422 may be formed of copper or other suitable metal to facilitate subsequent bonding. In some embodiments, the bond pad features 422 may be formed by suitable fabrication techniques such as electroplating or deposition. In some embodiments, the bond pad features 422 may be formed by a damascene process, such as a single damascene process or a dual-damascene process. The bond pad features 422 are configured to bond with bond pad features on a second die. The bond pad features 422 are arranged within a region corresponding to the second die and in a pattern matching bond pad features in the second die. FIG. 16B schematically demonstrates the distribution of the bond pad features 422 in the bonding film 420. The number of the bond pad features 422 may be less than or more than what is depicted in FIG. 16B. The bond pad features 422 may be designated based on the demand and/or design layout. In some embodiments, a top surface of the bond pad features 422 and a top surface of the bonding film 420 are substantially coplanar so as to provide an appropriate surface for the subsequent bonding. The planarity may be achieved, for example, through a planarization step such as a chemical mechanical polishing (CMP) step or a mechanical grinding step. After planarization, the first die 406 has a substantially planar bonding surface 406b including areas of the bonding film 420 and areas of the bond pad features 422.

In some embodiments, a portion of the bond pad features 422 are connected to through semiconductor vias (TSVs) 424. The TSVs 424 are embedded in the substrate. In some embodiments, the TSVs 424 may be formed of copper or other suitable metal that is easy for forming a D-D (dielectric-dielectric) and M-M (metal-metal) bonding. In some embodiments, the TSVs 424 may be formed in at the same time with the bond pad features 422 by a damascene process. In other embodiments, the TSVs 424 may be previously fabricated during the front end of the line processes with the device layer 414. The TSVs 424 may be used to provide electrical connection between the first die 406 and a second die to be bonded to the first die 406. First ends of the TSVs 424 are in contact with the bond pad features 422 and second ends of the TSVs 424 are in contact with the conductive features 418 in the interconnect structure 416. The conductive features 418 may be connected with the active components and/or passive comments in the device layer 414.

FIG. 16C schematically demonstrates the distribution of the TSVs 424 in the substrate 412. The number of the TSVs 424 may be less than or more than what is depicted in FIG. 16C. The number and lay out of the TSVs 424 are designated based on the demand and/or design layout.

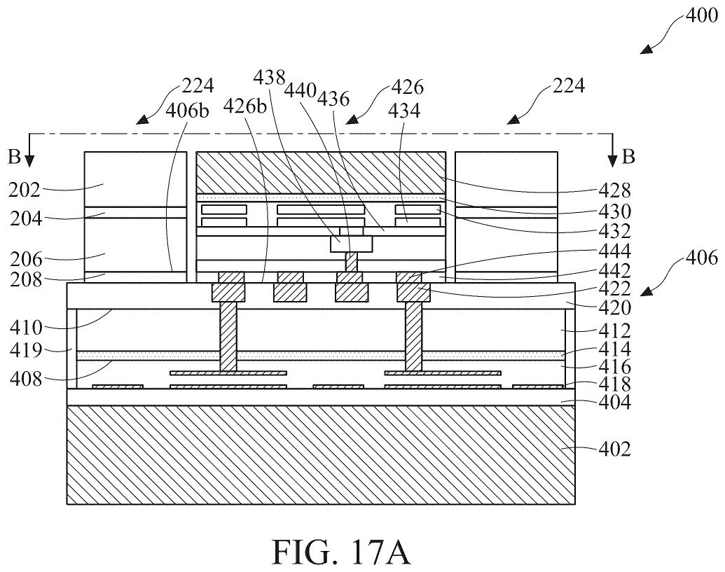

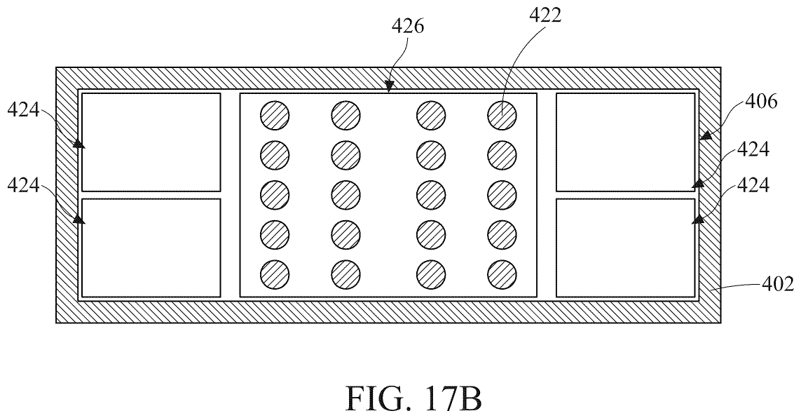

In operation 308, a second die 426 and one or more dummy dies 224 are bonded to the first die 406, as show in FIGS. 17A-17B. FIG. 17A is a schematic cross-sectional view of the IC package 400 after operation 308. FIG. 17B is a plane view of the IC package along B-B line on FIG. 17A.

The second die 426 may be a logic die, a memory die, a 3DIC die, a CPU die, a GPU (die, a SoC die, a MEMS die, or the like. The second die 426 may be a single die or a composition die, such as a chiplet having two or more dies. In some embodiments, the second die 426 may be a memory die.

The second die 426 may include a substrate 428, a device layer 430 formed in and on the substrate 428, and an interconnect structure 432 formed on the device layer 430. The interconnect structure 432 may include multiplayers of dielectric materials having conductive features 434 formed therein. The second die 426 may include a dielectric layer 436 formed over the interconnect structure 432. The dielectric layer 436 includes bond pads 438 and bond vias 440 embedded therein. A bonding film 442 is formed on the dielectric layer 436. Bond pad features 444 are formed in the bonding film 442.

The substrate 428 may comprise bulk silicon, doped or undoped, or an active layer of a SOI substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates. The device layer 430 is formed on the front side of the substrate 428. In operation 308, the second die 426 is bonded to the first die 406 with a back side of substrate 428 facing up.

The device layer 430 include a variety of devices, such as transistors, capacitors, resistors, inductors and the like, which may be used to generate the desired structural and functional requirements of the design for the second die 426.

The interconnect structure 432 is formed over the front side of the substrate 428 over the device layer 430. The conductive features 434 embedded in the interconnect structure 432 are designed to connect the various devices in the device layer 430 to form functional circuitry. The interconnect structure 432 is formed of alternating layers of dielectric and conductive material and may be formed through any suitable processes, such as deposition, damascene, dual damascene, etc.

The dielectric layer 436 may include one or more dielectric layers. In some embodiments, the material of the dielectric layer 436 may be silicon oxide, silicon nitride, silicon oxynitride, or a dielectric layer formed by other suitable dielectric materials. In some embodiments, the dielectric layer 436 may be undoped silicon glass, lower-k material, extreme low-k material, silicon oxide, or the like. The bond pads 438 and bond vias 440 may be formed by aluminum, aluminum copper, or the other suitable conductive material.

In some embodiments, the bonding film 442 may be formed of silicon oxide, silicon oxynitride, silicon nitride, or low-k dielectric materials having k values lower than about 3.0. The low-k dielectric materials may include carbon-containing low-k dielectric material, Hydrogen SilsesQuioxane (HSQ), MethylSilsesQuioxane (MSQ), or the like. In some embodiments, the bonding film 442 may be formed by suitable fabrication techniques such as chemical vapor deposition (CVD), High-Density Plasma Chemical Vapor Deposition (HDPCVD) or plasma-enhanced chemical vapor deposition (PECVD).

The bond pad features 444 may be formed of copper or other suitable metal to facilitate subsequent bonding. In some embodiments, the bond pad features 444 may be formed by suitable fabrication techniques such as electroplating or deposition. In some embodiments, the bond pad features 444 may be formed by a damascene process, such as a single damascene process or a dual-damascene process. The bond pad features 444 are configured to bond with the bond pad features 422 on the first die 406. In some embodiments, the bond pad features 444 are arranged in the same layout mirroring the bond pad features 422. A portion of the bond pad features 444 are in contact with the bond pads 438 by the bond vias 440 to provide electrical connection to components in the device layer 430.

In some embodiments, a top surface of the bond pad features 444 and a top surface of the bonding film 442 are substantially coplanar so as to provide an appropriate surface for the subsequent bonding. The planarity may be achieved, for example, through a planarization step such as a chemical mechanical polishing (CMP) step or a mechanical grinding step. After planarization, the second die 426 has a substantially planar bonding surface 426b including areas of the bonding film 442 and areas of the bond pad features 444.

In some embodiments, the first die 406 and the second die 426 may be bonded face-to-face as shown FIG. 17A. The bonding film 442 of the second die 426 is bonded to the bonding film 420 of the first die 406 through the dielectric-to-dielectric bonding, and the bond pad features 444 of the second die 426 are bonded to the bond pad features 422 of the first die 406 through the metal-to-metal bonding. The bonding process may be referred to as D-D and M-M bonding.

Before bonding the second die 426 to the first die 406, the second die 426 may be picked-up and placed onto the bonding surface 406b of the first die 406 such that the bonding surface 406b of the first die 406 is in direct contact with the bonding surface 426b of the second die 426, and the bond pad features 422 and 444 are aligned and in direct contact. In some embodiments, to facilitate the D-D and M-M bonding between the first die 406 and the second die 426, surface preparation for the bonding surfaces of the first die 406 and second die 426 may be performed. The surface preparation may include surface cleaning and activation, for example. In some embodiments, the bonding surface 406b of the first die 406 and the bonding surface 426b of the second die 426 may be cleaned by wet cleaning.

After bonding, a D-D and M-M bonding surface is formed between the first die 406 and the second die 426. In some embodiments, the metal-to-metal bonding at the D-D and M-M bonding interface is copper-to-copper bonding. In some embodiments, the dielectric-to-dielectric bonding at the D-D and M-M bonding interface is achieved with Si—O—Si bonds generated. After bonding, the first die 406 is electrically connected to the second die 426 by the bonding between the bond pad features 444 and the bond pad features 422. During the D-D and M-M bonding process, a low temperature heating process at a temperature range between about 100° C. and about 280° C. is performed to strengthen the dielectric-to-dielectric bonding at the D-D and M-M bonding interface. A high temperature heating process is performed at a temperature in a range between about 100° C. and about 400° C. to facilitate the metal-to-metal bonding at the D-D and M-M bonding interface.

As shown in FIG. 17B, the second die 426 is smaller than the first die 406. One or more dummy dies 224 are bonded to the first die 406 so that the bottom layer and the top layer are substantially the same size. FIG. 17B depicts four dummy dies 224. Less or more dummy dies 224 may be included depending on the design of the IC package 400.

Shape and dimension of each dummy die 224 may be selected according to the shapes, dimensions, and relative position of the first die 406 and the second die 426. The surface area of each dummy die 224 may be selected according to the surface area of the larger die or the first die 406 in the IC package 400. In some embodiments, a ratio of the surface area of each dummy die 224 over the surface area of the first die 406 may be in a range between about 7.5% and about 10%. The shape of the dummy dies 224 may be rectangular, square, or other shapes conform with the layout.

Before bonding the dummy dies 224 to the first die 406, the dummy dies 224 may be picked-up from the frame, such as the frame 228′ in FIG. 10 and placed onto the bonding surface 406b of the first die 406 such that the bonding surface 406b of the first die 406 is in direct contact with the bonding film 208 of the dummy die 224. In some embodiments, to facilitate the D-D and M-M bonding between the dummy dies 224 and the second die 426, surface preparation for the bonding surfaces of the first die 406 and dummy dies 224 may be performed. The surface preparation may include surface cleaning and activation.

The dummy dies 224 are stacked on the first die 406 and bonded thereon. The dummy dies 224 are disposed side-by-side with each other and with the second die 426. In some embodiments, the dummy dies 224 are fusion-bonded with the first die 406. In other words, the dummy dies 224 are bonded with the first die 406 through dielectric-to-dielectric bonding. In some embodiments, the dummy dies 224 may be bonded by a low temperature heating process at a temperature range between about 100° C. and about 280° C. to strengthen the dielectric-to-dielectric bonding. In some embodiments, bonding the dummy dies 224 to the first die 406 and bonding the second die 426 to the first die 406 may be performed in the same D-D and M-M bonding process. Alternatively, bonding the dummy dies 224 to the first die 406 and bonding the second die 426 to the first die 406 may be performed in separate bonding processes.

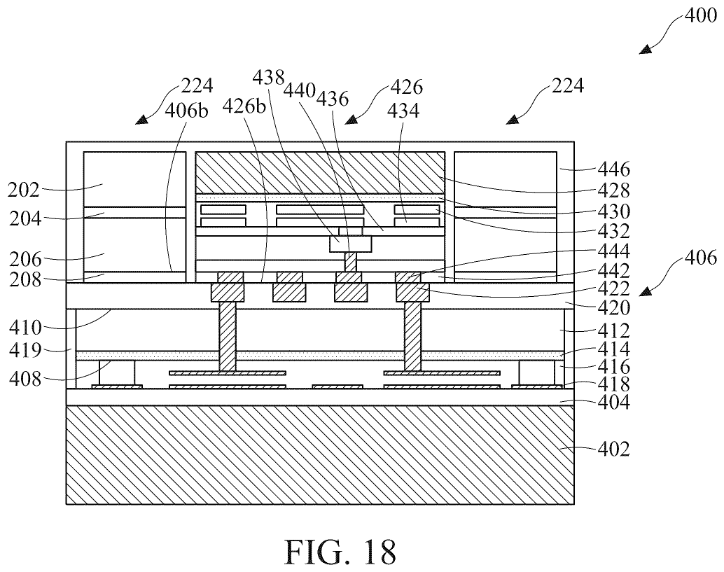

In operation 310, a dielectric film 446 is deposited over the IC package 400 to fill gaps between the dummy dies 224 and the second die 426, as shown in FIG. 18. FIG. 18 is a schematic cross-sectional view of the IC package 400 after operation 310. In some embodiments, the dielectric film 446 may include an oxide material, such as silicon oxide (SiO), TEOS, BPTEOS, or the like. The dielectric film 446 may also be a nitride material. The dielectric film 446 may also be a low-k dielectric material, a polymer material, other dielectric material, the like, or combinations thereof. The dielectric film 446 may also be formed by plasma enhanced chemical vapor deposition (PECVD), low pressure CVD (LPCVD), plasma vapor deposition (PVD), or the like.

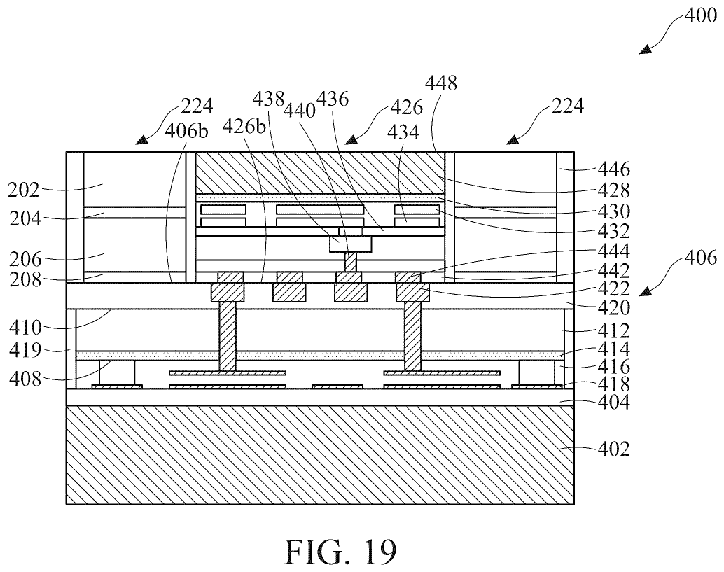

In operation 312, a planarization process is performed, as shown in FIG. 19. FIG. 19 is a schematic cross-sectional view of the IC package 400 after operation 312. The planarization process removes excess dielectric film 446 over the dummy dies 224 and the second die 426. The planarization process may also be used to thin down the dummy dies 224 and the second die 426 and to generate a planar surface 448 for further process.

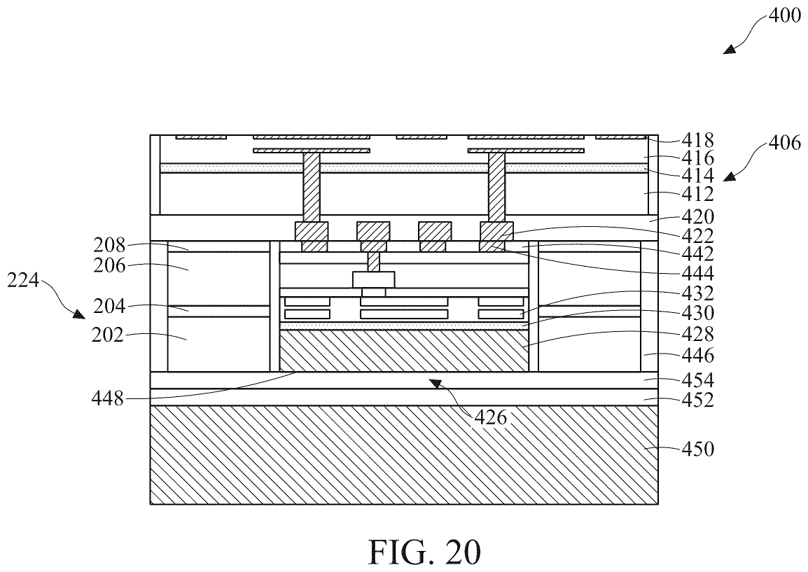

In operation 314, a second carrier wafer 450 is attached to the IC package 400 on the surface 448, as shown in FIG. 20. FIG. 20 is a schematic cross-sectional view of the IC package 400 after operation 314. In some embodiments, a bonding film 452 is formed over the second carrier wafer 450. A bonding film 454 is formed over the planar surface 448 of the IC package 400. In some embodiments, the bonding film 208 is formed of an oxide material. For example, the bonding films 452, 454 may include a dielectric material, such as silicon oxide, silicon oxynitride, or the like.

The IC package 400 is attached to second carrier wafer 450 by bonding the bonding films 452, 454. After the second carrier wafer 450 is attached to the IC package 400, the first carrier wafer 402 may be removed, and the IC package 400 flipped over to form contacts over the front side of the first die 406. In some embodiments, a surface preparation, such as surface cleaning and activation, may be performed to expose a topmost layer of the conductive features 418 for subsequent processing.

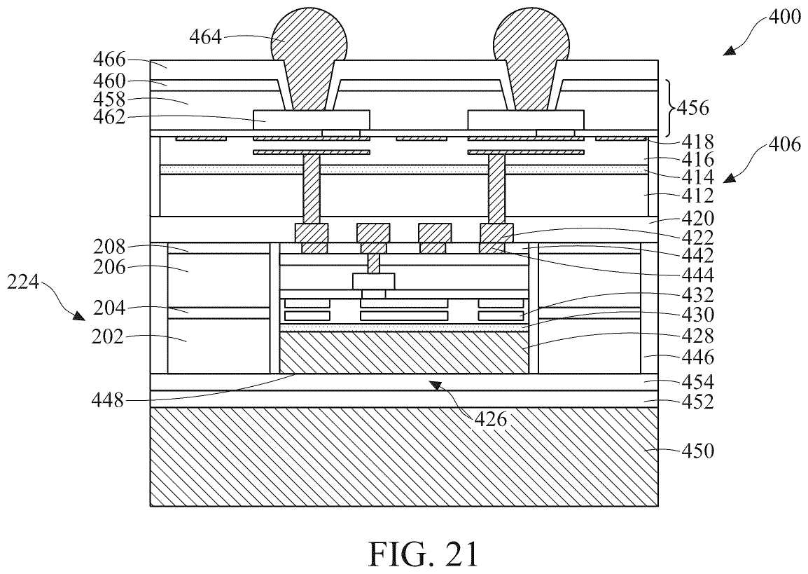

In operation 316, a RDL (redistribution layer) structure 456 and external connectors 464 are formed over the first die 406, as shown in FIG. 21. FIG. 21 is a schematic cross-sectional view of the IC package 400 after operation 314.

The RDL structure 456 may comprise one or more conductive layers 462 formed in on or more passivation layers 458. In some embodiments, the RDL structure 456 may include a protection layer 460 disposed over the passivation layers 458. The passivation layer 458 may be formed from a nitride base material. The protection layer 460 may be formed from silicon oxide, silicon nitride, or a combination. The conductive layers 462 may include metals such as aluminum, copper, tungsten, titanium, and combinations thereof. The RDL structure 456 may be formed by depositing the conductive layers 462 through chemical vapor deposition and then etching the undesired portions, leaving the RDL structure 456. Other materials and process, such as a well-known damascene process, could alternatively be used to form the RDL structure 456.

The external connectors 464 may be contact bumps such as micro bumps or controlled collapse chip connection (C4) bumps. The external connectors 464 may comprise a material such as tin, or other suitable materials, such as silver or copper. In some embodiments, the external connectors 464 are tin solder bumps formed by any suitable method such as evaporation, electroplating, printing, solder transfer, ball placement, etc. Once a layer of tin has been formed on the structure, a reflow is performed in order to shape the material into the desired bump shape. A protective layer 466 may be formed between the RDL structure 456 and the external connectors 464. In some embodiments, the protective layer 466 may be formed from polyimide, or the like.

As shown in FIG. 21, the substrate 202 in the dummy dies 224 and substrate 412 the first die 406 are bonded via the bonding film 420, the bonding film 208, the adjustment layer 206, and the adhesive layer 204. During operation, heat generated in the device layer 414 may dissipate from the substrate 412 to the substrate 202 via the bonding layers, i.e., the bonding film 420, the bonding film 208, the adjustment layer 206, and the adhesive layer 204. Because the adjustment layer 206 has improved thermal conductivity, the heat dissipation is improved. Additionally, the effective bonding length between the dummy dies 224 and the first die 406 also improves because the adjustment layer 206 is used to induce a warpage of the dummy dies 224 to improve bonding quality. Improved bonding quality further improves heat transfer between the dummy die 224 and the first die 406.

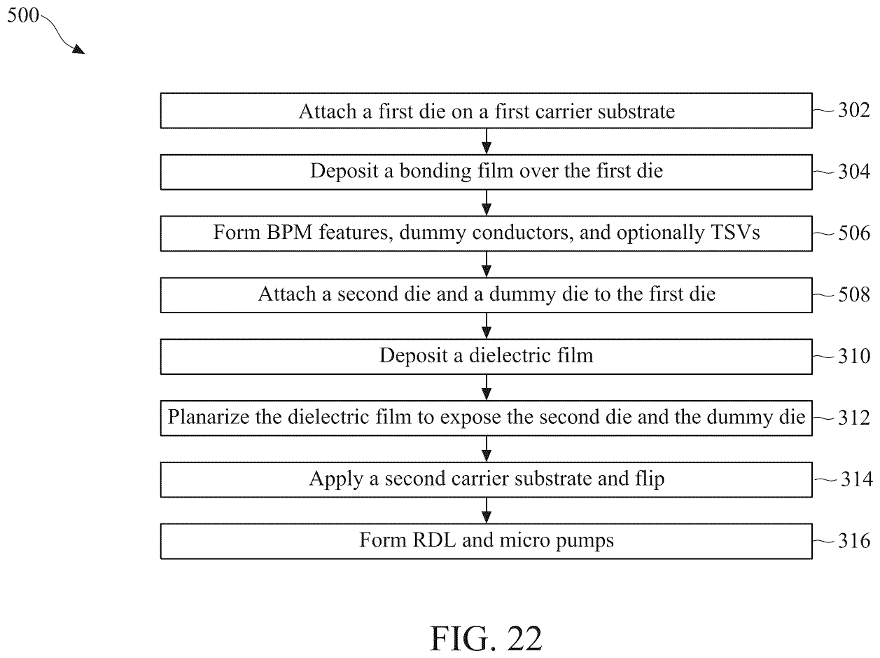

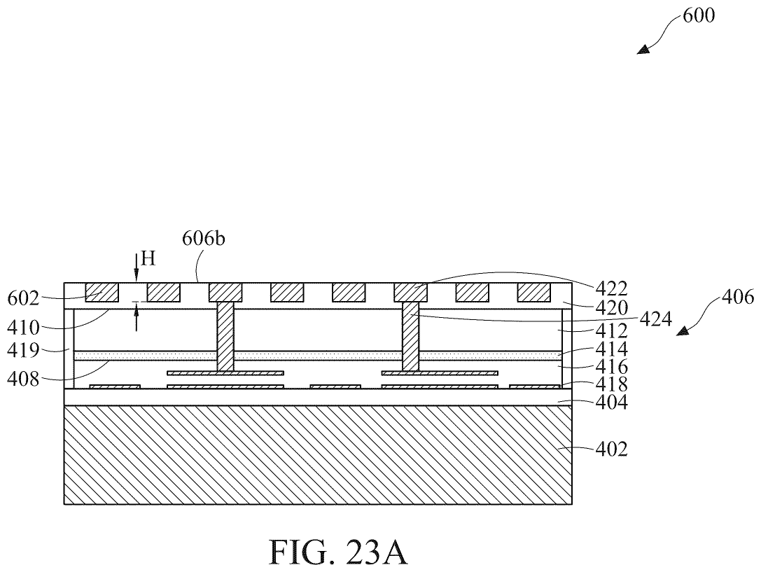

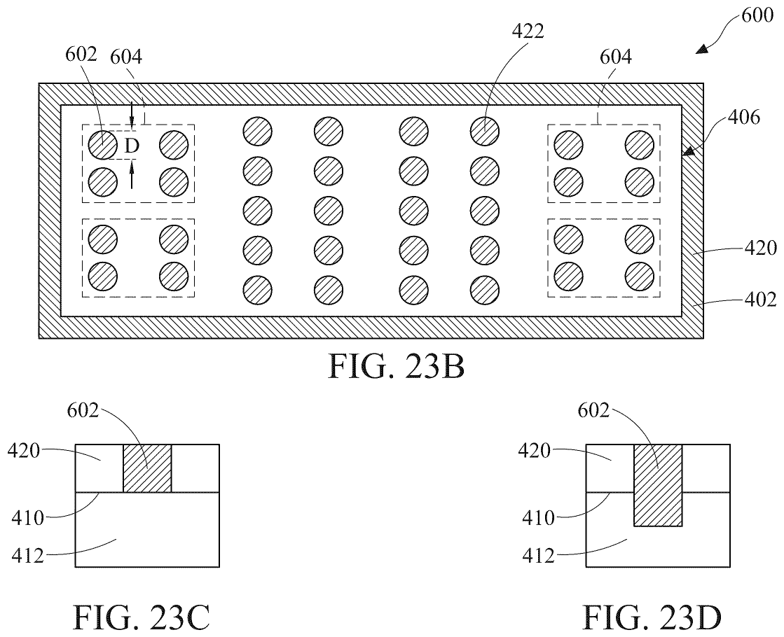

FIG. 22 is a flow diagram illustrating a method 500 of forming of an integrated circuit package according to embodiments of the present disclosure. FIGS. 23A-23D, 24A-24C, and 25 schematically demonstrate various processing stages during fabrication of an IC package 600 using the method 500.

The method 500 is similar to the method 300 except that the method 500 includes operations 506 and 508 in place of the operations 306 and 308 in the method 300. In operation 506, dummy conductors are formed in a first die. In operation 508, dummy dies are bonded to the first die in areas of with the dummy conductors. The method 500 starts with the operations 302 and 304. The corresponding phases may be depicted in FIGS. 14 and 15.

In operation 506, dummy conductors 602 are formed in the bonding film 420 in addition to the bond pad features 422, as shown in FIGS. 23A-23D. FIG. 23A is a schematic cross-sectional view of the IC package 600 after operation 506. FIG. 23B is a plane view of the IC package 600. FIGS. 23C and 23D are partial sectional views showing a dummy conductor according to embodiments of the present disclosure.

The dummy conductors 602 are conductive features, such as vias or lines, formed in the bonding film 420. The dummy conductors 602 are configured to further improve thermal conductivities between the first die 406 and the dummy die 224.

Similar to the bond pad features 422, the dummy conductors 602 are conductive features, lines and/or vias, formed in the bonding film 420. As discussed above, at least a portion of the bond pad features 422 are connected to the TSVs 424 formed in the substrate 412 of the first die 406. The bond pad features 422 are also intended to connect with conductors in the die to be bonded, such as the bond pad features 444 in the second die 426. Unlike the bond pad features 422, the dummy conductors 602 electrically float in the bonding film 420. That is the dummy conductors 602 are not connected to any conductors in the first die 406. The dummy conductors 602 are also not connected to any conductive features in the die to be bonded, such as the dummy die 224.

The dummy conductors 602 may be formed of copper or other suitable metal. In some embodiments, the dummy conductors 602 may be formed by suitable fabrication techniques such as electroplating or deposition. The dummy conductors 602 may be formed by forming trenches and vias in the bonding film 420 and filling the trenches and vias in the bonding film 420. In some embodiments, the dummy conductors 602 may be formed by a damascene process, such as a single damascene process or a dual-damascene process. In some embodiments, the dummy conductors 602 may be formed simultaneously with the bond pad features 422.

After operation 506, top surfaces of the of the dummy conductors 602 and the bond pad features 422 and a top surface of the bonding film 420 are substantially coplanar so as to provide an appropriate surface for the subsequent bonding. The planarity may be achieved, for example, through a planarization step such as a chemical mechanical polishing (CMP) step or a mechanical grinding step. After planarization, the first die 406 has a substantially planar bonding surface 606b including areas of the bonding film 420, areas of the bond pad features 422, and areas of the dummy conductors 602.

In some embodiments, the dummy conductors 602 may have a height H in the bonding film 420. In some embodiments, the height H of the dummy conductors 602 may be in arrange between about 1 k angstroms to about 20 k angstroms. In some embodiments, the height H of the dummy conductors 602 may be substantially the same as the height of the bond pad features 422.

In some embodiments, the height H of the dummy conductors 602 may be embedded in the bonding film 420, as shown in FIG. 23A. In other embodiments, the dummy conductors 602 may have the same thickness of the bonding film 420 so that the dummy conductors 602 is in contact with the back side 410 of the substrate 412, as shown in FIG. 23C. In other embodiments, the height H of the dummy conductors 602 may greater than the thickness of the bonding film 420 so that the dummy conductors 602 extends into the substrate 412, as shown in FIG. 23D.

FIG. 23B schematically demonstrates the distribution of the dummy conductors 602 in the bonding film 420. As shown in FIG. 23B, the dummy conductors 602 are arranged with areas of the bonding film 420 configured to receive dummy dies in the subsequent bonding. FIG. 23B is a schematic depiction of the dummy conductors 602. The number, shape, and arrangement of the dummy conductors 602 may be arranged in any suitable manner. In some embodiments, a total surface area of dummy conductors 602 may be selected first. Shape and layout of the dummy conductors 602 may be determined to achieve to total surface area.

In some embodiments, the total areas of the dummy conductors 602 may be determined by a surface area of the dummy die to bond with. For example, a ratio of the total surface areas of the dummy conductors 602 to bond with a dummy die over a surface area of the dummy die may be in a range between about 0.03 and abut 0.3.

In other embodiments, the surface area of the first die 406, i.e., the die on which the dummy conductors 602 are formed, may affect the total surface area of the dummy conductors 602. For example, a ratio of the total surface areas of the dummy conductors 602 over the surface area of the first die 406 may be in a range between about 0.001 and abut 0.01.

In other embodiments, the surface area of the second die 426, i.e., the non-dummy die to bond with the first die 406, may also affect the total surface area of the dummy conductors 602. For example, a ratio of the total surface areas of the dummy conductors 602 over the surface area of the second die 426 may be in a range between about 0.003 and abut 0.03.

The dummy conductors 602 may be any suitable shapes and in a suitable arrangement to achieve to total surface area. For example, the dummy conductors 602 may be conductive vias, having a diameter D in a range between about 0.01 mm and about 0.1 mm. In other embodiments, the dummy conductors 602 may be conductive lines having a width in a range between about 0.01 mm and about 0.1 mm and a length between about 1 mm and about 10 mm. In some embodiments, the dummy conductors 602 may have the same shape. In other embodiments, the dummy conductors 602 may be in a combination of shapes.

In some embodiments, the dummy conductors 602 may be distributed in one or more dummy areas 604. Each dummy area 604 may have a shape similar to the dummy die 224 to be bonded thereon. The dummy area 604 may be slightly smaller than the surface area of the dummy die 224 so that a conductor-free band is formed around an edge of the dummy die 224 after bonding described in the operation 508.

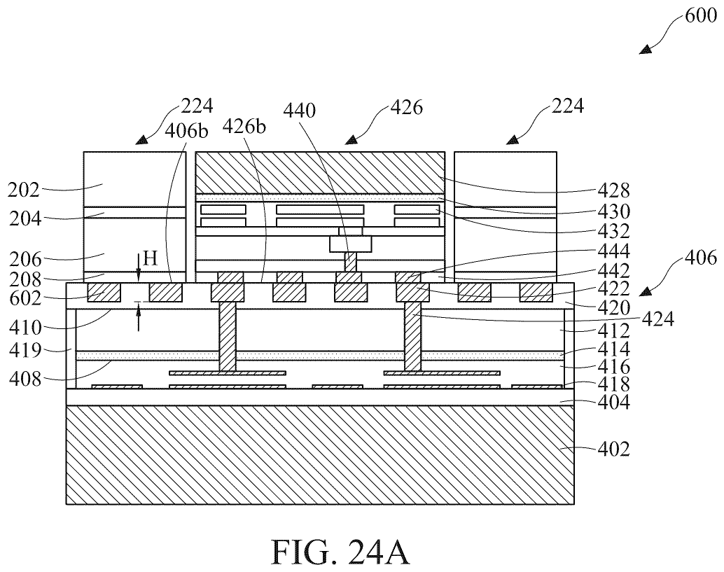

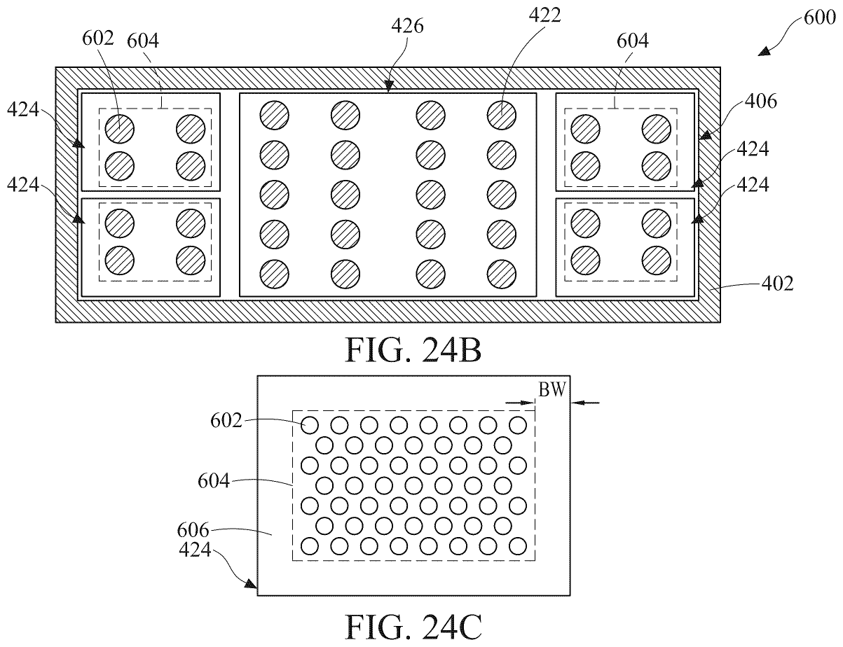

In operation 508, the second die 426 and one or more dummy dies 224 are bonded to the first die 406, as show in FIGS. 24A-24C. FIG. 24A is a schematic cross-sectional view of the IC package 600 after operation 508. FIG. 24B is a plane view of the IC package 600. FIG. 24C is a partial plane view showing distribution of the dummy conductors 602 with relative to the dummy die 224 after bonding.

The first die 406 and the second die 426 may be bonded face-to-face by a D-D and M-M bonding process, as described above with the operation 308. The dummy dies 224 are bonded to the first die 406 with the dummy conductors 602 in the bonding surface. The dummy dies 224 are positioned side-by-side with each other and with the second die 426 and over areas of the dummy conductors 602. In some embodiments, the dummy dies 224 are fusion-bonded with the first die 406. In some embodiments, the dummy dies 224 may be bonded by a low temperature heating process at a temperature range between about 100° C. and about 280° C. to strengthen the dielectric-to-dielectric bonding.

In some embodiments, the dummy dies 224 are aligned with and positioned over the corresponding dummy areas 604 so that a conductor-free band 606 is formed within an edge region of each dummy die 224, as shown in FIG. 24C. The conductor-free band 606 reduces non-bonding length near the edge region of the dummy die 224, thus improving bonding quality. In some embodiments, the conductor-free band 606 may have a width BW in a range between about 1 mm and about 2 mm.

In some embodiments, bonding the dummy dies 224 to the first die 406 and bonding the second die 426 to the first die 406 may be performed in the same D-D and M-M bonding process. Alternatively, bonding the dummy dies 224 to the first die 406 and bonding the second die 426 to the first die 406 may be performed in separate bonding processes.

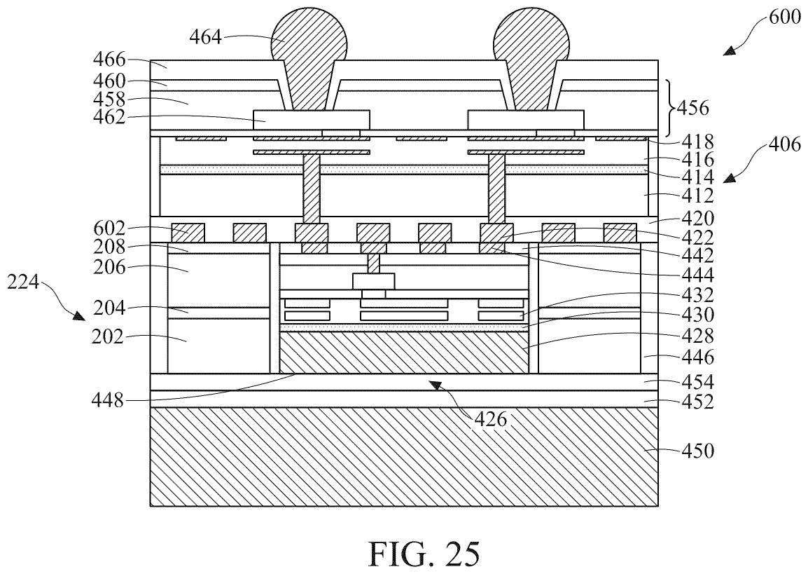

After the operation 508, operations 310, 312, 314, and 316 may be performed as described with the method 300 above. FIG. 25 is a schematic cross-sectional view of the IC package 600 after operation 314.

As shown in FIG. 25, the substrate 202 in the dummy dies 224 and substrate 412 the first die 406 are bonded via a film stack including the bonding film 420 with the dummy conductors 602, the bonding film 208, the adjustment layer 206, and the adhesive layer 204. During operation, heat generated in the device layer 414 may dissipate from the substrate 412 to the substrate 202 via the film stack. In addition to the material in the adjustment layer 206, thermal conductivity of the film stack is further reduced by the presence of the dummy conductors 602 in the bonding film 420.

Embodiments of the present disclosure provide a dummy die with an improved bonding structure. Particularly, the dummy die according to the present disclosure increases thermal conductivity through the dummy die, enhances warpage adjustment with a thinner film. Embodiments of the present disclosure further comprises dummy conductors to bond with the dummy die, which further increases thermal conductivity. Increased thermal conductivity leads to improved heat dissipation in IC packages according to the present disclosure.

It will be understood that not all advantages have been necessarily discussed herein, no particular advantage is required for all embodiments or examples, and other embodiments or examples may offer different advantages.

Some embodiments of the present disclosure relate to a semiconductor package comprising: a first die having a first bonding film; a second die stacked over the first die and bonded to the first die via the first bonding film; and a dummy die stacked over the first die and bonded to the first die via the first bonding film, wherein dummy die comprises: a substrate; an adjustment layer formed over the substrate, wherein the adjustment layer has a thermal conductivity in a range between about 30 W/mK and about 100 W/mK; and a second bonding film formed over the adjustment layer, wherein the second bonding film is bonded to the first bonding film.

Some embodiments of the present disclosure relate to a method comprising: bonding a first die to a second die, wherein the first die comprises a first bonding film, and the second die is bonded to the first bonding film; and bonding a dummy die to the first die, wherein the dummy die comprises: a substrate; an adjustment layer formed over the substrate, wherein the adjustment layer has a thermal conductivity in a range between about 30 W/mK and about 100 W/mK; and a second bonding film formed over the adjustment layer, and the first bonding film is bonded to the second bonding film.

Some embodiments of the present disclosure relate to a method for forming dummy dies, comprises: depositing an adjustment layer on a front side of a semiconductor substrate; depositing a bonding film on the adjustment layer; forming a dicing pattern over the bonding film; etching through the bonding film, the adjustment layer, and into the semiconductor substrate using the dicing pattern to form dicing trenches; depositing a protection layer in the dicing trenches and on the bonding film; attaching a carrier wafer to the protection layer; and grinding the semiconductor substrate from a back side to expose the protection layer in the dicing trenches.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor package, comprising:
a first die having a first bonding film;
a second die stacked over the first die and bonded to the first die via the first bonding film;
a dummy die stacked over the first die and bonded to the first die via the first bonding film, wherein dummy die comprises:
a substrate; and
a second bonding film, wherein the second bonding film is bonded to the first bonding film; and
one or more dummy conductors formed in the first bonding film, wherein the one or more dummy conductors are in contact with the second bonding film.

2. The semiconductor package of claim 1, wherein the first bonding film includes a band surrounding the one or more dummy conductors, the band is in contact with an edge region of the dummy die, and the one or more dummy conductors are disposed within the band.

3. The semiconductor package of claim 2, wherein the band has a width in a range between about 1 mm and about 2 mm.

4. The semiconductor package of claim 1, further comprising:
a plurality of bond pad features formed in the first bonding film, wherein the plurality of bond pad features are facing the second die.

5. The semiconductor package of claim 1, wherein the first die comprises:
a substrate portion; and
a device layer formed on a first side of the substrate portion, wherein the first bonding film is formed on a second side of the substrate portion, and the one or more dummy conductors are in contact with the substrate portion.

6. The semiconductor package of claim 5, wherein the one or more dummy conductors extend into the substrate portion.

7. The semiconductor package of claim 1, wherein the dummy die further comprises an adjustment layer formed between the second bonding film and the substrate.

8. The semiconductor package of claim 7, wherein the adjustment layer has a thermal conductivity in a range between about 30 W/mK and about 100 W/mK.

9. The semiconductor package of claim 7, wherein the adjustment layer comprises silicon nitride or silicon carbide.

10. The semiconductor package of claim 7, wherein the adjustment layer has a thickness between about 3 k angstroms and about 6 k angstroms.

11. The semiconductor package of claim 1, wherein the second bonding film has a thickness between about 100 angstrom and 1000 angstroms.

12. The semiconductor package of claim 11, wherein the second bonding film comprises silicon oxide.

13. A method, comprising:
bonding a first die to a second die, wherein the first die comprises a first bonding film, one or more dummy conductors are formed in the first bonding film, and the second die is bonded to the first bonding film; and
bonding a dummy die to the first die, wherein the dummy die comprises:
a substrate; and
a second bonding film, wherein the one or more dummy conductors are bonded to the second bonding film.

14. The method of claim 13, wherein the first bonding film includes a band surrounding the one or more dummy conductors, the band is aligned with an edge region of the dummy die, and the one or more dummy conductors are disposed within the band.

15. The method of claim 14, wherein the band has a width in a range between about 1 mm and about 2 mm.

16. The method of claim 13, wherein the first die further comprises:
a plurality of bond pad features formed in the first bonding film, wherein the plurality of bond pad features are facing the second die.

17. The method of claim 13, wherein the first die comprises:
a substrate portion; and
a device layer formed on a first side of the substrate portion, wherein the first bonding film is formed on a second side of the substrate portion, and the one or more dummy conductors are in contact with the substrate portion.

18. The method of claim 17, wherein the one or more dummy conductors extend into the substrate portion.

19. A method, comprises:
attaching a first die on a first carrier substrate;
depositing a first bonding film on the first die;
forming a plurality of bond pad features and one or more dummy conductors in the first bonding film;
attaching a second die to the first bonding film, wherein the second die faces the plurality of bond pad features;
attaching a dummy die to the first bonding film, wherein the dummy die faces the one or more dummy conductors;
depositing a dielectric film;
planarizing the dielectric film to expose the second die and the dummy die;
applying a second carrier substrate to the second die and the dummy die;
removing the first carrier substrate; and
forming a redistribution layer (RDL) on the first die.

20. The method of claim 19, wherein forming the one or more dummy conductors comprises depositing the one or more dummy conductors into a substrate portion of the first die.
